(19) United States
(12) Patent Application Publication
(10) Pub. No.: US 2025/0248155 A1
(43) Pub. Date: Jul. 31, 2025

(54) PIXEL ARRAY, IMAGE SENSOR, AND ELECTRONIC DEVICE INCLUDING THEM

(71) Applicant: Samsung Electronics Co., Ltd., Suwon-si (KR)

(72) Inventors: Junsik Lee, Suwon si (KR); Chulsoo Choi, Suwon si (KR); Jonghoon Park, Suwon-si (KR); Yunki Lee, Suwon-si (KR)

(21) Appl. No.: 19/040,067

(22) Filed: Jan. 29, 2025

(30) Foreign Application Priority Data
Jan. 29, 2024 (KR) 10-2024-0013197

(51) Int. Cl. H10F 39/00

(52) U.S. Cl. CPC H10F 39/806; H10F 39/805

(57) ABSTRACT

Provided is an image sensor including a pixel array including a plurality of pixels, the plurality of pixels each including a sensor layer including a first light sensing cell and a second light sensing cell, a color separation lens layer configured to receive first light having a first wavelength sensed by the first light sensing cell and second light having a second wavelength sensed by the second light sensing cell, and an anti-reflective coating layer configured to reduce reflection of light received by the color separation lens layer, wherein the anti-reflective coating layer has a grid pattern having the same shrink ratio as a grid pattern of the color separation lens layer.

### CROSS-REFERENCE TO RELATED APPLICATION

This application is based on and claims priority under 35 U.S.C. § 119 to Korean Patent Application No. 10-2024-0013197, filed on Jan. 29, 2024, in the Korean Intellectual Property Office, the disclosure of which is incorporated by reference herein in its entirety.

### BACKGROUND

Aspects of the inventive concept relate to a pixel array, an image sensor, and an electronic device including them, and more particularly, to a pixel array including a plurality of color separation lenses, wherein the pixel array includes anti-reflective coatings corresponding to the plurality of color separation lenses.

An image sensor commonly senses the color of incident light by using a color filter. However, because the color filter absorbs the other colors of light except for a corresponding color of light, light use efficiency may decrease. For example, when a red, green, and blue (RGB) color filter is used, the RGB color filter transmits only ⅓ of incident light therethrough and absorbs the other ⅔, and thus, the light use efficiency of the RGB color filter is merely about 33%. Therefore, for a color display device or a color image sensor, most optical losses occur in a color filter.

Recently developed image sensors and electronic devices including an image sensor include a pixel array to which a color separation lens is applied to prevent the optical loss described above.

However, the color separation lens has high reflectance according to a light incident condition, and an image sensor outputs an image including an interference pattern due to the high reflectance.

### SUMMARY

Aspects of the inventive concept provide an image sensor, which includes an anti-reflective coating corresponding to a color separation lens and reduces light reflected from the color separation lens.

Aspects of the inventive concept also provide an image sensor including an anti-reflective coating corresponding to a color separation lens to reduce a waffle phenomenon occurring in an output image and to cancel noise.

According to an aspect of the inventive concept, an image sensor includes a pixel array comprising a plurality of pixels, the plurality of pixels each comprising: a sensor layer comprising a first light sensing cell and a second light sensing cell; a color separation lens layer configured to receive first light having a first wavelength sensed by the first light sensing cell and second light having a second wavelength sensed by the second light sensing cell and change paths of each of the received first light and the received second light; and an anti-reflective coating layer configured to reduce reflection of light received by the color separation lens layer, wherein the anti-reflective coating layer has a grid pattern having the same shrink ratio as a grid pattern of the color separation lens layer.

According to another aspect of the inventive concept, a pixel array of an image sensor includes a plurality of pixels, the pixel array comprising: a sensor layer comprising a plurality of first light sensing cells and a plurality of second light sensing cells; a color separation lens layer configured to receive first light having a first wavelength sensed by the plurality of first light sensing cells and second light having a second wavelength sensed by the plurality of second light sensing cells and change paths of each of the received first light and the received second light; and an anti-reflective coating layer configured to reduce reflection of light received by the color separation lens layer, wherein the anti-reflective coating layer has a grid pattern having the same shrink ratio as a grid pattern of the color separation lens layer.

According to another aspect of the inventive concept, an image sensor including a pixel array composed of a plurality of pixels is applied to an electronic device, the plurality of pixels each including a sensor layer comprising a first light sensing cell and a second light sensing cell; a color separation lens layer configured to receive first light having a first wavelength sensed by the the first light sensing cell and second light having a second wavelength sensed by the the second light sensing cell and change paths of each of the received first light and the received second light; and an anti-reflective coating layer configured to reduce reflection of light received by the color separation lens layer, wherein the anti-reflective coating layer has a grid pattern having the same shrink ratio as a grid pattern of the color separation lens layer.

### BRIEF DESCRIPTION OF THE DRAWINGS

Embodiments of the inventive concept will be more clearly understood from the following detailed description taken in conjunction with the accompanying drawings in which:

FIG. 1 is a block diagram of an image sensor according to an embodiment;

FIG. 2 is a block diagram illustrating a pixel array according to an embodiment;

FIG. 3 is a structural diagram of a pixel array according to an embodiment;

FIGS. 4A, 4B, and 4C illustrate a structure of anti-reflective coatings according to an embodiment;

FIG. 5 is a structural diagram of a sensor layer according to an embodiment;

FIG. 6A illustrates a grid pattern of a color separation lens layer according to an embodiment;

FIG. 6B illustrates a grid pattern of an anti-reflective coating layer according to an embodiment;

FIGS. 7A and 7B illustrate an image derived when an anti-reflective coating according to an embodiment is not applied;

FIG. 8 illustrates an image derived when an anti-reflective coating according to an embodiment is applied;

FIG. 9 is a graph illustrating the reflectance of a pixel array according to an embodiment;

FIG. 10 is a graph illustrating the color ratio of an image derived when an anti-reflective coating according to an embodiment is not applied; and

FIG. 11 is a graph illustrating the color ratio of an image derived when an anti-reflective coating according to an embodiment is applied.

### DETAILED DESCRIPTION OF THE EMBODIMENTS

Hereinafter, embodiments are described with reference to the accompanying drawings. Hereinafter, details, such as detailed features and structures, are provided to help those of ordinary skill in the art understand the embodiments. Therefore, the embodiments described herein may be changed or modified within the scope without departing from the inventive concept.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

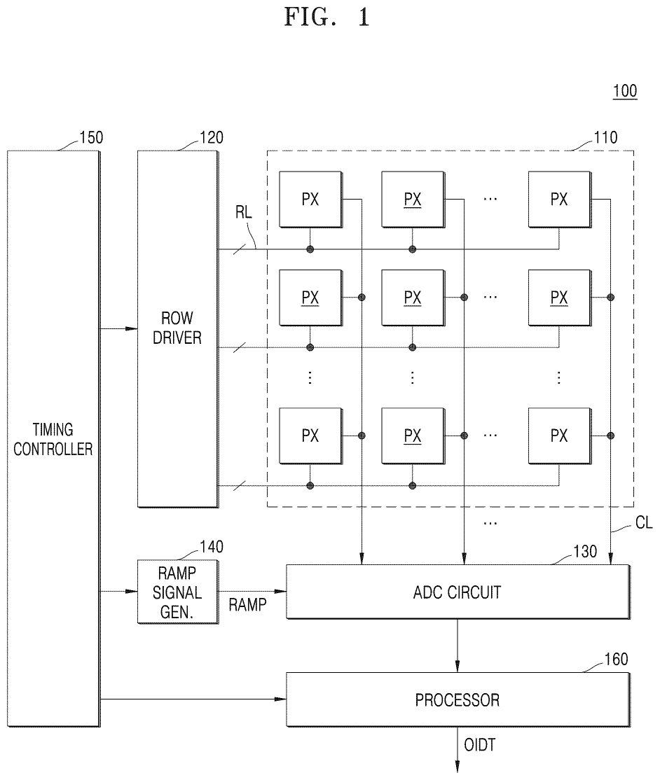

FIG. 1 is a block diagram of an image sensor 100 according to an embodiment.

Referring to FIG. 1, the image sensor 100 may include a pixel array 110, a row driver 120, an analog-digital converter (ADC) circuit 130, a ramp signal generator 140, a timing controller 150, and a processor 160.

The pixel array 110 may include a plurality of pixels PX arranged in a matrix form and a plurality of row lines RL and a plurality of column lines CL connected to the plurality of pixels PX. According to an embodiment, each of the plurality of pixels PX may include at least one photoelectric conversion device (or light-sensing device), wherein a photoelectric conversion device may sense light and convert the sensed light into photocharges. For example, a photoelectric conversion device may be a light-sensing device, such as an inorganic photodiode (PD), an organic PD, a perovskite PD, a phototransistor, a photogate, or a pinned PD, formed of an organic material or an inorganic material. In an embodiment, each of the plurality of pixels PX may include a plurality of photoelectric conversion devices. The plurality of photoelectric conversion devices may be arranged on the same layer or stacked one on another in the vertical direction.

A microlens for light concentration may be on each of the plurality of pixels PX or each of pixel groups each including adjacent pixels PX. Each of the plurality of pixels PX may sense a certain spectral area of light from light received through the microlens.

According to an embodiment, the pixel array 110 may include pixels PX having a red, green, and blue (RGB) pattern or a red, green, blue, and white color (RGBWC) pattern. For example, the pixel array 110 may include red pixels configured to convert a red spectral area of light into an electrical signal, green pixels configured to convert a green spectral area of light into an electrical signal, and blue pixels configured to convert a blue spectral area of light into an electrical signal. In addition, the pixel array 110 may include white pixels configured to convert light having all components of the red spectral area, the green spectral area, and the blue spectral area into an electrical signal. A color filter configured to transmit therethrough a certain spectral area of light may be on each of the plurality of pixels PX. However, the pixel array 110 is not limited thereto and may include pixels configured to convert spectral areas of light different from the red, green, and blue spectral areas into electrical signals.

According to an embodiment, the plurality of pixels PX may have a multi-layer structure. A pixel PX having the multi-layer structure may include light-sensing devices stacked to convert different spectral areas of light into electrical signals and generate electrical signals corresponding to different colors from the light-sensing devices. In other words, one pixel PX may output electrical signals corresponding to a plurality of colors.

In addition, the pixel array 110 may include the plurality of row lines RL and the plurality of column lines CL. Each of the plurality of row lines RL may extend in the row direction and be connected to pixels PX on the same row. For example, each of the plurality of row lines RL may transfer control signals output from the row driver 120 to each of devices, e.g., a plurality of transistors, in a pixel PX.

Each of the plurality of column lines CL may extend in the column direction and may be connected to pixels PX on the same column. Each of the plurality of column lines CL may transfer, to the ADC circuit 130, a pixel signal, e.g., a reset signal or a sensing signal, output from pixels PX in a row unit of the pixel array 110.

Under control by the timing controller 150, the row driver 120 may generate control signals for driving the pixel array 110 and provide the control signals to each of the plurality of pixels PX in the pixel array 110 through the plurality of row lines RL. The row driver 120 may control the plurality of pixels PX in the pixel array 110 to sense incident light at the same time or in a row unit. In addition, the row driver 120 may select pixels PX from among the plurality of pixels PX in a unit of one row or at least two rows and control the selected pixels PX to output pixel signals through the plurality of column lines CL.

The ADC circuit 130 may receive a plurality of pixel signals read out from pixels PX on a row selected by the row driver 120 from among the plurality of pixels PX and convert the plurality of pixel signals into a plurality of pixel values that are digital data.

The ADC circuit 130 may convert a plurality of pixel signals received from the pixel array 110 through the plurality of column lines CL into digital data based on a ramp signal RAMP from the ramp signal generator 140 to generate and output first image data, i.e., raw image data, in a row unit.

The ADC circuit 130 may include a plurality of ADCs respectively corresponding to the plurality of column lines CL, wherein each of the plurality of ADCs may compare a pixel signal received through a corresponding column line CL to the ramp signal RAMP and generate a pixel value based on the comparison result. For example, an ADC may remove a reset signal from a sensing signal by correlated double sampling (CDS) and generate a pixel value indicating the intensity of light sensed by a pixel PX.

The ramp signal generator 140 may generate the ramp signal RAMP ascending or descending with a certain gradient and provide the ramp signal RAMP to the ADC circuit 130.

The timing controller 150 may control timings of other components, e.g., the row driver 120, the ADC circuit 130, the ramp signal generator 140, and the processor 160, of the image sensor 100. The timing controller 150 may provide timing signals indicating operation timings to the row driver 120, the ADC circuit 130, the ramp signal generator 140, and the processor 160, respectively.

The processor 160 may process data for the plurality of pixel values input from the ADC circuit 130. The processor 160 may perform image quality compensation, binning, downsizing, and the like on image data. Accordingly, image-processed output image data OIDT may be generated and output in a certain unit.

For example, the processor 160 may process image data for each color. For example, if image data includes red, green, and blue pixel values, the processor 160 may process the red, green, and blue pixel values in parallel or series. In addition, the processor 160 may process image data for each color in parallel and include a plurality of processing circuits.

According to an embodiment, the image sensor 100 may be mounted in an electronic device having an image-or light-sensing function. For example, the image sensor 100 may be mounted in an electronic device, such as a camera, a smartphone, a wearable device, an Internet of Things (IoT) device, a home appliance, a tablet personal computer (PC), a personal digital assistant (PDA), a portable multimedia player (PMP), a navigation device, a drone, or an advanced driver assistance system (ADAS). In addition, the image sensor 100 may be mounted in an electronic device provided as a part to vehicles, furniture, manufacturing equipment, doors, various kinds of measurement instruments, and the like.

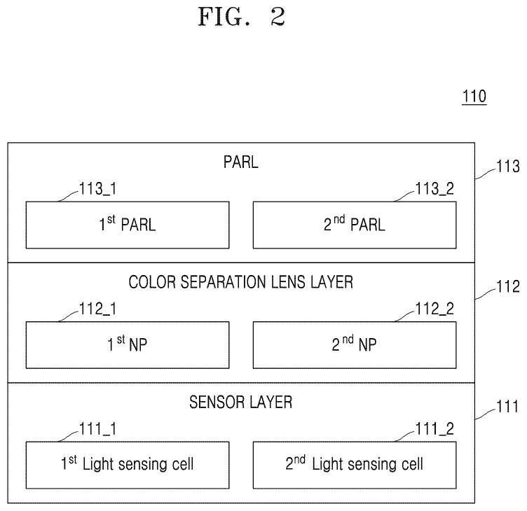

FIG. 2 is a block diagram illustrating a plurality of pixels according to an embodiment.

Referring to FIG. 2, the pixel array 110 according to an embodiment may include a plurality of pixels. According to an embodiment, each of the plurality of pixels may include a sensor layer 111, a color separation lens layer 112, and an anti-reflective coating layer 113.

According to an embodiment, the sensor layer 111 may include a first light sensing cell 111_1 and a second light sensing cell 111_2, which sense light. According to an embodiment, each light sensing cell may sense a certain color of light. According to an embodiment, the sensor layer 111 may include a plurality of light sensing cells having an RGB pattern. For example, each of the first light sensing cell 111_1 and the second light sensing cell 111_2 may sense light having a certain wavelength. According to an embodiment, the first light sensing cell 111_1 may sense light having a blue-based wavelength and the second light sensing cell 111_2 may sense light having a red-based wavelength. According to another embodiment, the first light sensing cell 111_1 may sense light having a red-based wavelength and the second light sensing cell 111_2 may sense light having a green-based wavelength. According to an embodiment, the terms “first” and “second” in the first light sensing cell 111_1 and the second light sensing cell 111_2 are only used to distinguish between a plurality of light sensing cells and have no intention to indicate sensing of light having a certain wavelength. Therefore, each of the first light sensing cell 111_1 and the second light sensing cell 111_2 may sense light having a red-based wavelength, a green-based wavelength, or a blue-based wavelength in accordance with circumstances. Hereinafter, in the specification, the wavelength of light sensed by the first light sensing cell 111_1 is referred to as a first wavelength and the wavelength of light sensed by the second light sensing cell 111_2 is referred to as a second wavelength.

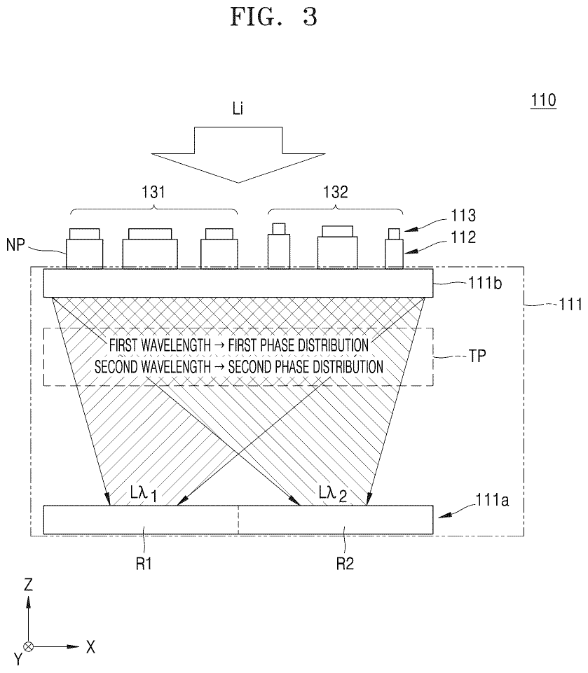

According to an embodiment, the color separation lens layer 112 may be configured to receive the first wavelength of light sensed by the first light sensing cell 111_1 and the second wavelength of light sensed by the second light sensing cell 111_2 and change each of the paths of the received first wavelength of light and second wavelength of light. For example, the color separation lens layer 112 may include a plurality of color separation lenses. According to an embodiment, a color separation lens may be a metasurface lens including nano posts (NP). According to an embodiment, an NP may be a part of a color separation lens including a nano prism. According to an embodiment, FIG. 2 shows individual nano posts 112_1 and 112_2 that correspond to individual light sensing cells 111_1 and 111_2. However, the inventive concept is not limited thereto. For example, as shown in FIG. 3, an array of nano posts NP may be positioned above the light sensing cells 111_1 and 111_2. The shape, size (width and height), spacing, arrangement form, and the like of the NPs may be determined such that incident white light is separated into light having the first wavelength, which is incident upon the first light sensing cell 111_1, and light having the second wavelength, which is incident upon the second light sensing cell 111_2.

For example, the color separation lens layer 112 may include a first color separation lens nano post 112_1 and a second color separation lens nano post 112_2. According to an embodiment, the nano posts NP of each color separation lens may be formed in a cylindrical shape. For example, the shapes of the nano posts NP of the first color separation lens nano post 112_1 and the second color separation lens nano post 112_2 may be cylindrical shapes. According to an embodiment, the first color separation lens nano post 112_1 and the second color separation lens nano post 112_2 may have the same volume or different volumes.

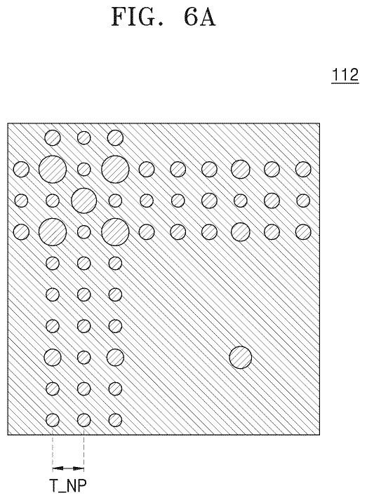

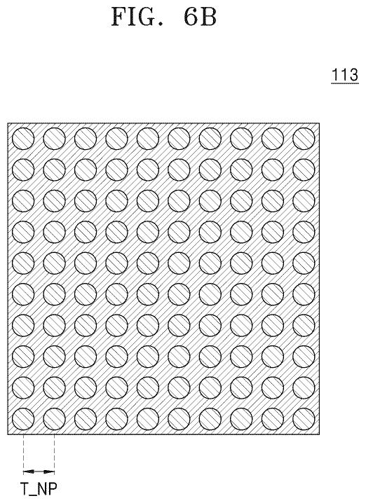

Although FIG. 2 shows that the color separation lens layer 112 includes the first color separation lens nano post 112_1 and the second color separation lens nano post 112_2, the number of color separation lenses is not limited thereto, and the color separation lens layer 112 may further include a plurality of color separation lenses. Further, the color separation lens layer 112 may be formed by repeating a unit pattern (such as the one shown in FIG. 6A) of nano posts NP and each unit pattern may be referred to as a color separation lens. Alternatively, each quadrant of the unit pattern may individually be referred to as a color separation lens. Alternatively, the entire repeating pattern may be referred to as a color separation lens.

According to an embodiment, the anti-reflective coating layer 113 may prevent or reduce reflection of light received by the color separation lens layer 112. As used herein, the phrase “reduce reflection” may mean the removal of some or all of the reflection of light received by the color separation lens layer 112. For example, the anti-reflective coating layer 113 may be configured such that the phase of light incident to the color separation lens layer 112 is the same as the phase of light incident to the anti-reflective coating layer 113. For example, the anti-reflective coating layer 113 may prevent reflection of light received by NPs included in the color separation lens layer 112, by aligning the phase of light incident to anti-reflective coatings included in the anti-reflective coating layer 113 with the phase of light incident to the NPs. According to an embodiment, the anti-reflective coatings included in the anti-reflective coating layer 113 may include a material that is the same as or different from that of the NPs, but the volume and the shape of the anti-reflective coatings or the NPs may be configured such that the phase of light incident to the anti-reflective coatings is aligned with the phase of light incident to the NPs. By configuring the pixel array 110 according to an embodiment such that the phase of light incident to the color separation lens layer 112 is the same as the phase of light incident to the anti-reflective coating layer 113, the pixel array 110 may reduce noise in an output image.

According to an embodiment, the anti-reflective coating layer 113 may have a lower refractive index than the color separation lens layer 112. For example, a material of the anti-reflective coating layer 113 may be a low-refractive material compared to a material of the color separation lens layer 112. For example, the color separation lens layer 112 may include a dielectric material, such as titanium dioxide (TiO₂), gallium nitride (GaN), silicon trinitride (SiN₃), zinc sulfide (ZnS), zinc selenide (ZnSe), or trisilicon tetranitride (Si₃N₄), having a low absorption factor in a visible light band with a high refractive index, and the anti-reflective coating layer 113 may include a dielectric material, such as air, silicon dioxide (SiO₂), or siloxane-based spin on glass (SOG), having a low absorption factor in the visible light band with a low refractive index.

According to an embodiment, a grid pattern of the anti-reflective coating layer 113 may have the same shrink ratio as a grid pattern of the color separation lens layer 112. According to an embodiment, having the same shrink ratio as a grid pattern of the color separation lens layer 112 may mean that a grid pattern of anti-reflective coatings included in the anti-reflective coating layer 113 is aligned with a grid pattern of the plurality of color separation lenses included in the color separation lens layer 112. For example, the grid pattern may be the pattern formed by the nano posts NP that constitute the color separation lens layer 112. For example, the anti-reflective coating layer 113 may include a plurality of anti-reflective coatings including first and second anti-reflective coatings 113_1 (“1^{st} PARL”) and 113_2 (“2^{nd} PARL”) and may be configured such that the grid pattern of the plurality of color separation lenses included in the color separation lens layer 112 is aligned with a grid pattern of the plurality of anti-reflective coatings. According to an embodiment, the grid pattern of the anti-reflective coating layer 113 may have the same shrink ratio as the grid pattern of the color separation lens layer 112 by aligning the centers of the plurality of anti-reflective coatings included in the anti-reflective coating layer 113 with the centers of the plurality of color separation lenses included in the color separation lens layer 112. FIG. 3 is a structural diagram of the pixel array 110 according to an embodiment.

Referring to FIG. 3, the color separation lens layer 112 may include NPs disposed on the same plane according to a certain rule. The color separation lens layer 112 may be on a spacer layer 111b. According to an embodiment, the NPs may include the first and second color separation lenses 112_1 and 112_2 of FIG. 2.

Herein, the shape, size (width and height), spacing, arrangement form, and the like of the NPs may be determined according to a target phase distribution TP, which the color separation lens layer 112 is intended to implement with respect to incident light Li. The target phase distribution TP may be determined by considering first and second target regions R1 and R2, on which light is to be concentrated by separating the wavelength of the incident light Li. Although the target phase distribution TP is between the color separation lens layer 112 and the first and second target regions R1 and R2, this is only for convenience of drawing. Actually, the target phase distribution TP means a phase distribution at a position immediately after the incident light Li passes through the color separation lens layer 112, for example, a phase distribution on the lower surface of the color separation lens layer 112 or the upper surface of the spacer layer 111b.

Each of the color separation lens layer 112 and the anti-reflective coating layer 113 may include a first region 131 and a second region 132 respectively having a first microstructure and a second microstructure different from each other. For example, each of the first region 131 and the second region 132 may include one or more NPs. The first region 131 and the second region 132 may face the first target region R1 and the second target region R2, respectively, and and may have a one to one correspondence with the first target region R1 and the second target region R2, respectively. Although FIG. 3 shows that three NPs are in each of the first region 131 and the second region 132, this is illustrative. In addition, although FIG. 3 shows that NPs are evenly positioned in each of the first region 131 and the second region 132, the inventive concept is not limited thereto, and some NPs may be positioned on the boundary between the first region 131 and the second region 132.

The NPs in the color separation lens layer 112 may form a phase distribution, in which different wavelengths of light included in the incident light Li branch off in different directions to concentrate the different wavelengths of light. For example, the shape, size, arrangement, and the like of NPs distributed in the first region 131 and the second region 132 may be determined for the target phase distribution TP such that a first wavelength of light Lλ1 included in the incident light Li has a first phase distribution and a second wavelength of light Lλ2 included in the incident light Li has a second phase distribution. According to this target phase distribution TP, the first wavelength of light Lλ1 and the second wavelength of light Lλ2 may respectively concentrate on the first and second target regions R1 and R2 separated by a certain separation distance from the color separation lens layer 112 including the NPs.

A rule of arranging NPs in the first region 131 may differ from a rule of arranging NPs in the second region 132. In other words, any one of the shape, size, and arrangement of NPs in the first region 131 may differ from a corresponding one of the shape, size, and arrangement of NPs in the second region 132.

An NP may have the shape dimension of a sub-wavelength less than a wavelength band of incident light, the traveling direction of which is intended to be changed by diffraction. The NP may have a shape dimension less than a shorter one of the first wavelength and the second wavelength. For example, if the incident light Li is visible light, the NP may have a dimension less than 400 nm, 300 nm, or 200 nm.

The NP may include a material having a refractive index higher than the refractive index of a surrounding material. For example, the NP may include crystalline silicon (c-Si), p-type silicon (p-Si), amorphous silicon (a-Si), a group III-V compound (gallium phosphide (GaP), GaN, gallium arsenide (GaAs), or the like), silicon carbide (SiC), TiO₂, silicon nitride (SiN), and/or a combination thereof. The NP having a refractive index difference from the surrounding material may change the phase of light passing through the NP. This is a reason of a phase delay caused by the shape dimension of a sub-wavelength, and a degree of the phase delay is determined by the detailed shape dimension, arrangement form, and the like of NPs. The surrounding material may include a dielectric material, e.g., SiO₂ or air, having a lower refractive index than the NP.

A first wavelength λ1 and a second wavelength λ2 may belong to a visible light wavelength band but are not limited thereto, and various wavelength bands may be implemented according to a rule of arranging NPs. Although FIG. 3 shows that two wavelengths branch off to concentrate the two wavelengths of light, the inventive concept is not limited thereto, and incident light may branch off in three or more directions according to wavelengths to concentrate the three or more wavelengths of light.

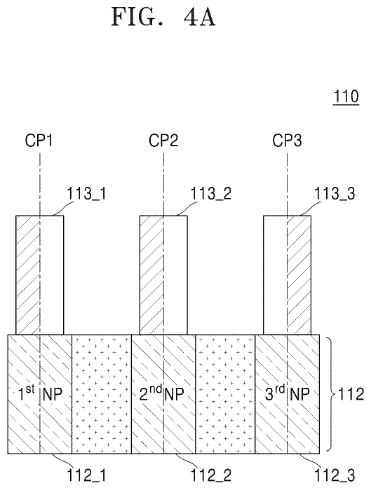

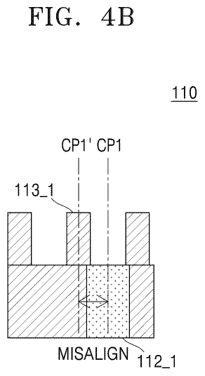

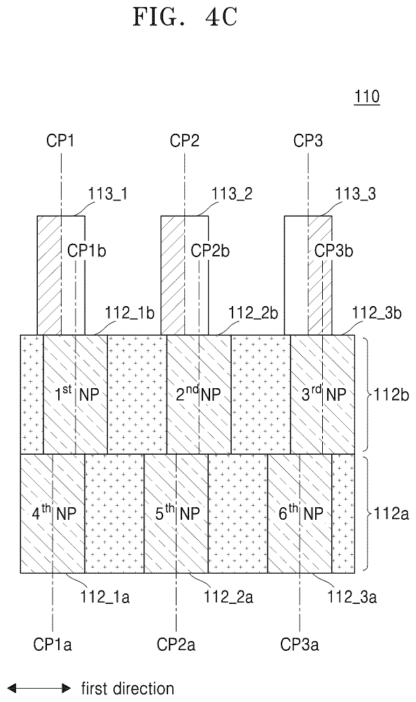

FIG. 4A illustrates a structure of anti-reflective coatings according to an embodiment. FIGS. 4B illustrates a structure in which a color separation lens layer 112 is misaligned with an anti-reflective coating layer 113 according to a comparative example. FIG. 4C illustrates a structure of anti-reflective coatings according to an embodiment.

Referring to FIGS. 2 and 4A, the pixel array 110 according to an embodiment may include the color separation lens layer 112, wherein the color separation lens layer 112 may include the first color separation lens nano post 112_1, the second color separation lens nano post 112_2, and a third color separation lens nano post 112_3. In addition, the anti-reflective coating layer 113 according to an embodiment may include a first anti-reflective coating 113_1, a second anti-reflective coating 113_2, and a third anti-reflective coating 113_3. Although FIG. 4A shows that the color separation lens layer 112 includes the first color separation lens nano post 112_1, the second color separation lens nano post 112_2, and the third color separation lens nano post 112_3 and the anti-reflective coating layer 113 includes the first anti-reflective coating 113_1, the second anti-reflective coating 113_2, and the third anti-reflective coating 113_3, the numbers of color separation lenses and anti-reflective coatings are not limited thereto, and a plurality of color separation lenses and anti-reflective coatings may be further included.

According to an embodiment, each of the color separation lenses nano posts may have a cylindrical shape, and a plurality of anti-reflective coatings may be on the plurality of color separation lenses, respectively. For example, the first anti-reflective coating 113_1 may be on the first color separation lens nano post 112_1, the second anti-reflective coating 113_2 may be on the second color separation lens nano post 112_2, and the third anti-reflective coating 113_3 may be on the third color separation lens nano post 112_3. According to an embodiment, the first anti-reflective coating 113_1, the second anti-reflective coating 113_2, and the third anti-reflective coating 113_3 may be provided to have centers respectively aligned with the centers of the first color separation lens nano post 112_1, the second color separation lens nano post 112_2, and the third color separation lens nano post 112_3.

For example, the anti-reflective coating layer 113 may be configured such that the centers of the first anti-reflective coating 113_1 and the first color separation lens nano post 112_1 are common to a first center line CP1, the centers of the second anti-reflective coating 113_2 and the second color separation lens nano post 112_2 are common to a second center line CP2, and the centers of the third anti-reflective coating 113_3 and the third color separation lens nano post 112 3 are common to a third center line CP3. According to an embodiment, the grid pattern of the anti-reflective coating layer 113 may be aligned with the grid pattern of the color separation lens layer 112 by respectively aligning the centers of the first anti-reflective coating 113_1, the second anti-reflective coating 113_2, and the third anti-reflective coating 113_3 with the centers of the first color separation lens nano post 112_1, the second color separation lens nano post 112_2, and the third color separation lens nano post 112_3. For example, the anti-reflective coating layer 113 may be configured to have a grid pattern having the same shrink ratio as the grid pattern of the anti-reflective coating layer 113 by respectively aligning the centers of the first anti-reflective coating 113_1, the second anti-reflective coating 113_2, and the third anti-reflective coating 113_3 with the centers of the first color separation lens nano post 112_1, the second color separation lens nano post 112_2, and the third color separation lens nano post 112_3.

Referring to FIG. 4B, the centers of an anti-reflective coating and a color separation lens according to a comparative example may be misaligned with each other. For example, the first center CP1 of the first color separation lens nano post 112_1 may deviate from a center CP1′ of the first anti-reflective coating 113_1. According to an embodiment, misalignment may be a degree of deviation of the center CP1′ of the first anti-reflective coating 113_1 from the first center CP1 of the first color separation lens nano post 112_1. In the pixel array 110 according to an embodiment, the color separation lens layer 112 may be aligned with the anti-reflective coating layer 113 by aligning the first center CPI of the first color separation lens nano post 112_1 with the center CP1′ of the first anti-reflective coating 113_1 as shown in FIG. 4A.

Referring further to FIG. 4C, the pixel array 110 according to an embodiment includes the color separation lens layer 112 and the anti-reflective coating layer 113, wherein the color separation lens layer 112 may consist of a plurality of tiers. For example, the color separation lens layer 112 may include a first tier 112a located at the lower part of the color separation lens layer 112 and a second tier 112b located at the upper part of the color separation lens layer 112. The first tier 112a may include a first color separation lens nano post 112_1a, a second color separation lens nano post 112_2a, and a third color separation lens nano post 112_3a, while the second tier 112b may include a fourth color separation lens nano post 112_1b, a fifth color separation lens nano post 112_2b, and a sixth color separation lens nano post 112_3b. Additionally, the anti-reflective coating layer 113 may include a first anti-reflective coating 113_1, a second anti-reflective coating 113_2, or a third anti-reflective coating 113_3.

The number of tiers included in the color separation lens layer 112 described in FIG. 4C and the number of color separation lenses are not limited thereto, and the layer may further include a plurality of tiers, a plurality of color separation lenses, and a plurality of anti-reflective coatings. Descriptions overlapping with those of FIGS. 2 and 4A are omitted.

In some embodiments, the anti-reflective coatings included in the anti-reflective coating layer 113 may be installed to align with average centers. Here, the average center may refer to the average of the center of a color separation lens nano post included in the first tier 112a and the center of a corresponding color separation lens nano post included in the second tier 112b. The average of the centers may refer to the midpoint (e.g., the middle point between two centers) along a first direction perpendicular to the stacking direction of the first tier 112a and the second tier 112b.

For example, the first anti-reflective coating 113_1 may be installed such that the center of the first anti-reflective coating 113_1 aligns with the first center CP1, which is the average of the center CP1a of the first color separation lens nano post 112_1a and the center CP1b of the fourth color separation lens nano post 112_1b. The second anti-reflective coating 113_2 may be installed such that the center of the second anti-reflective coating 113_2 aligns with the second center CP2, which is the average of the center CP2a of the second color separation lens nano post 112_2a and the center CP2b of the fifth color separation lens nano post 112_2b. The third anti-reflective coating 113_3 may be installed such that the center of the third anti-reflective coating 113_3 aligns with the third center CP3, which is the average of the center CP3a of the third color separation lens nano post 112_3a and the center CP3b of the sixth color separation lens nano post 112_3b.

The anti-reflective coating layer 113 according to an embodiment may align the grid pattern of the anti-reflective coating layer 113 with the grid pattern of the color separation lens layer 112 by matching the first anti-reflective coating 113_1, the second anti-reflective coating 113_2, and the third anti-reflective coating 113_3 respectively with the first center CP1, the second center CP2, and the third center CP3. For example, the first anti-reflective coating 113_1, the second anti-reflective coating 113_2, and the third anti-reflective coating 113_3 may be configured to have the same shrink ratio as the grid pattern of the color separation lens layer 112 by aligning with the first center CP1, the second center CP2, and the third center CP3, respectively.

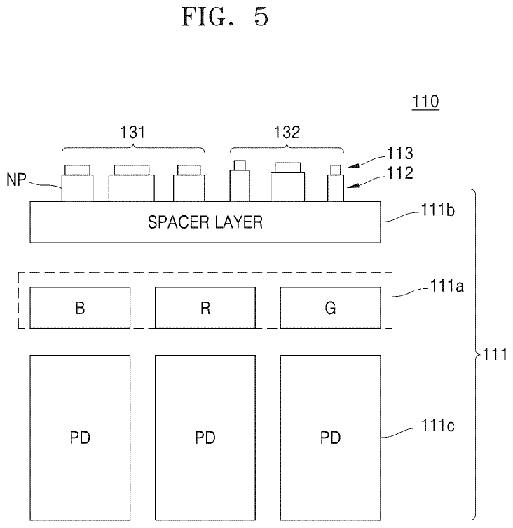

FIG. 5 is a structural diagram of the sensor layer 111 according to an embodiment.

Referring to FIGS. 3 and 5, the pixel array 110 according to an embodiment may include the sensor layer 111, the color separation lens layer 112, and the anti-reflective coating layer 113, wherein each of the color separation lens layer 112 and the anti-reflective coating layer 113 may include the first region 131 and the second region 132 respectively having the first microstructure and the second microstructure different from each other. The color separation lens layer 112, the anti-reflective coating layer 113, the first region 131, and the second region 132 according to an embodiment are the same as the embodiment of FIG. 3, and thus, the sensor layer 111 embodied in the embodiment of FIG. 3 is mainly described herein.

According to an embodiment, the sensor layer 111 may include a color sensing area 111a, a spacer layer 111b, and a PD area 111c.

According to an embodiment, the color sensing area 111a may have, e.g., an RGB Bayer pattern. According to an embodiment, the sensor layer 111 may include the color sensing area 111a including light sensing cells and having an RGB pattern to separate and sense light having a certain wavelength. For example, any one or more light sensing cells in the color sensing area 111a may sense light having a blue-based wavelength, any one or more light sensing cells may sense light having a red-based wavelength, and the remaining light sensing cells may sense light having a green-based wavelength.

According to an embodiment, the color separation lens layer 112 may be on the spacer layer 111b. For example, a plurality of NPs may be on or beneath the spacer layer 111b. According to an embodiment, the plurality of NPs may include the first and second color separation lenses 112_1 and 112_2 of FIG. 2.

According to an embodiment, the PD area 111c may include a plurality of photodiodes (PDs) and convert light energy into electrical energy. For example, each of the plurality of PDs may sense light and convert the sensed light into photocharges. According to an embodiment, each of the plurality of PDs may be a light-sensing device, such as an inorganic PD, an organic PD, a perovskite PD, a phototransistor, a photogate, or a pinned PD, formed of an organic material or an inorganic material. According to an embodiment, the plurality of PDs may be in the same layer or stacked in the vertical direction.

FIG. 6A illustrates a grid pattern of the color separation lens layer 112 according to an embodiment, and FIG. 6B illustrates a grid pattern of the anti-reflective coating layer 113 according to an embodiment.

Referring to FIG. 6A, the color separation lens layer 112 according to an embodiment may have a grid pattern with a predefined color separation lens spacing (T_NP). For example, the grid pattern may have the predefined color separation lens spacing (T_NP) between color separation lenses. According to an embodiment, the predefined color separation lens spacing (T_NP) may be a value determined when the color separation lens layer 112 was manufactured.

Referring to FIG. 6B, the grid pattern of the anti-reflective coating layer 113 according to an embodiment may be the same as the grid pattern of the color separation lens layer 112 of FIG. 6A. For example, the anti-reflective coating layer 113 may have the grid pattern having the predefined color separation lens spacing (T_NP). According to an embodiment, the predefined color separation lens spacing (T_NP) of FIG. 6B may be the same as the predefined color separation lens spacing (T_NP) of FIG. 6A. For example, the grid pattern may have the predefined color separation lens spacing (T_NP) between anti-reflective coatings. According to an embodiment, the predefined color separation lens spacing (T_NP) may be a value determined when the anti-reflective coating layer 113 was manufactured.

Referring to FIGS. 6A and 6B, the anti-reflective coating layer 113 may include a plurality of anti-reflective coatings and may be configured such that the grid pattern of the plurality of color separation lenses included in the color separation lens layer 112 is aligned with the grid pattern of the plurality of anti-reflective coatings. For example, a grid spacing of the plurality of color separation lenses may be the predefined color separation lens spacing (T_NP) and a grid spacing of the plurality of anti-reflective coatings may also be the predefined color separation lens spacing (T_NP). According to an embodiment, the grid pattern of the anti-reflective coating layer 113 may have the same shrink ratio as the grid pattern of the color separation lens layer 112 by aligning the centers of the plurality of anti-reflective coatings included in the anti-reflective coating layer 113 with the centers of the plurality of color separation lenses included in the color separation lens layer 112.

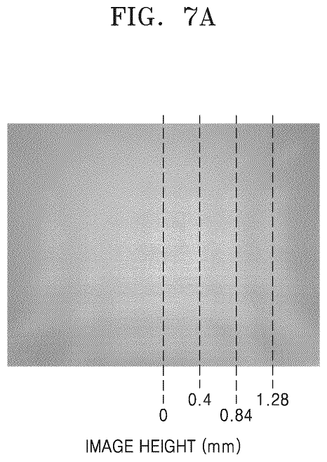

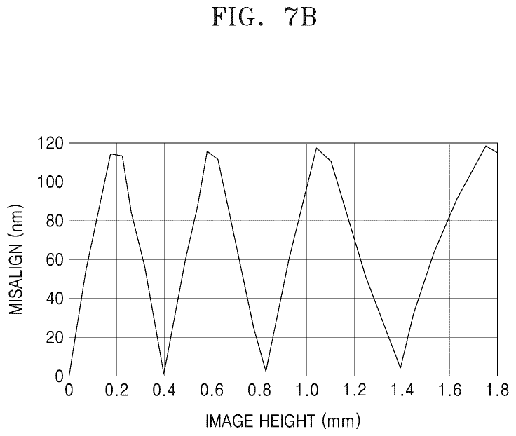

FIGS. 7A and 7B illustrate an image derived when a misaligned anti-reflective coating is applied according to a comparative example.

Referring to FIGS. 2 and 7A, when the anti-reflective coating layer 113 according to an embodiment is not applied (e.g., when a misaligned anti-reflective coating layer is applied), the pixel array 110 according to an embodiment may output an image with a waffle or moiré phenomenon. According to an embodiment, the waffle phenomenon may mean that an interference phenomenon is included in an output image resulting from a portion of light received by the color separation lens layer 112 being reflected. According to an embodiment, the spacing of an interference pattern may occur in a constant period. According to an embodiment, an image height may be the distance measured from the center of an image.

Referring to FIG. 7B, when misalignment occurs between an anti-reflective coating and a color separation lens according to an embodiment, an interference phenomenon present in an image pattern may be proportional to a misalignment period. In the graph of FIG. 7B according to an embodiment, the x-axis indicates an image height and the y-axis indicates a degree of misalignment between the anti-reflective coating layer 113 and the color separation lens layer 112. For example, when first misalignment occurs, an interference pattern may appear near a 0.2 mm point of an output image and the interference pattern may not appear between the anti-reflective coating layer 113 and the color separation lens layer 112 near a 0.4 mm point of the output image. In addition, when second misalignment occurs, an interference pattern may appear near a 0.6 mm point of the output image, and the interference pattern may not appear between the anti-reflective coating layer 113 and the color separation lens layer 112 near a 0.8 mm point of the output image.

Referring back to FIG. 7A, in the pixel array 110 having the misalignment tendency of FIG. 7B, the period of the interference pattern of the output image may be about 0.4 mm. That is, the period of the interference pattern has the tendency of being the same as the misalignment period of the color separation lens layer 112 and the anti-reflective coating layer 113.

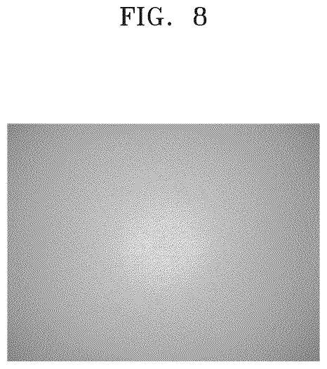

FIG. 8 illustrates an image derived when an anti-reflective coating according to an embodiment is applied.

Referring to FIGS. 2 and 8, when the anti-reflective coating layer 113 according to an embodiment is applied, the pixel array 110 according to an embodiment may output an image without a waffle phenomenon. According to an embodiment, the grid pattern of the anti-reflective coating layer 113 may have the same shrink ratio as the grid pattern of the color separation lens layer 112. According to an embodiment, having the same shrink ratio as the grid pattern of the color separation lens layer 112 may mean that the grid pattern of anti-reflective coatings included in the anti-reflective coating layer 113 is aligned with the grid pattern of the plurality of color separation lenses included in the color separation lens layer 112. For example, the anti-reflective coating layer 113 may include a plurality of anti-reflective coatings including the first and second anti-reflective coatings 113_1 and 113_2 and may be configured such that the grid pattern of the plurality of color separation lenses included in the color separation lens layer 112 is aligned with the grid pattern of the plurality of anti-reflective coatings. According to an embodiment, the anti-reflective coating layer 113 may have a grid pattern having the same shrink ratio as the grid pattern of the color separation lens layer 112 by aligning the centers of the plurality of anti-reflective coatings included in the anti-reflective coating layer 113 with the centers of the plurality of color separation lenses included in the color separation lens layer 112, and the image sensor 100 may output an image with reduced noise.

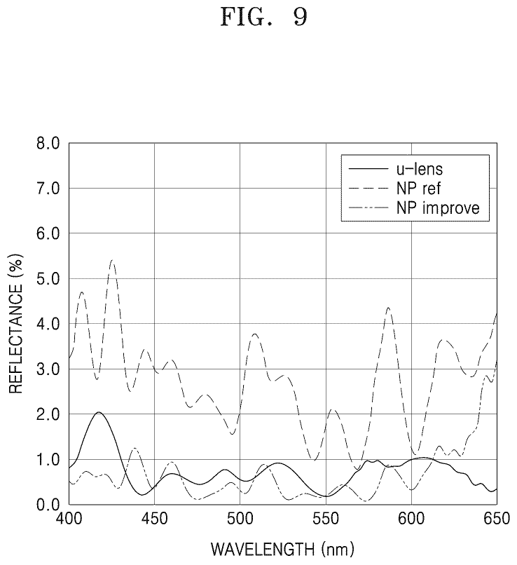

FIG. 9 is a graph illustrating the reflectance of a pixel array according to an embodiment. In the graph of FIG. 9, the x-axis may indicate the wavelength of incident light and the y-axis may indicate reflectance.

Referring to FIG. 9, a reflectance u-lens of an example including only a pixel array to which a color separation lens according to an embodiment is not applied has a value of around 1%. A reflectance NP ref of an example to which only a color separation lens layer according to an embodiment is applied has a value of around 3% to 4%. However, a reflectance NP improve of an example to which both a color separation lens layer and an anti-reflective coating layer according to an embodiment are applied has a value less than 1%. However, the values of the reflectance u-lens of the example including only a pixel array to which a color separation lens according to an embodiment is not applied, the reflectance NP ref of the example to which only a color separation lens layer according to an embodiment is applied, and the reflectance NP improve of the example to which both a color separation lens layer and an anti-reflective coating layer according to an embodiment are applied may vary according to applied embodiments, but the tendency of each of the reflectance u-lens, the reflectance NP ref, and the reflectance NP improve may be maintained. That is, there is the tendency that the value of the reflectance NP improve of the example to which both a color separation lens layer and an anti-reflective coating layer according to an embodiment are applied is less than the value of the reflectance u-lens of the example including only a pixel array to which a color separation lens according to an embodiment is not applied and less than the value of the reflectance NP ref of the example to which only a color separation lens layer according to an embodiment is applied.

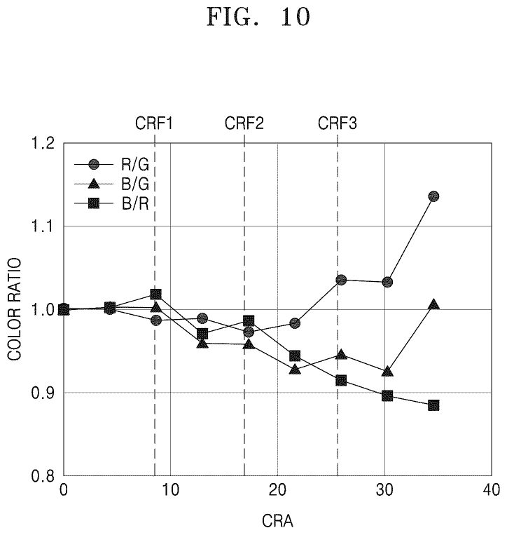

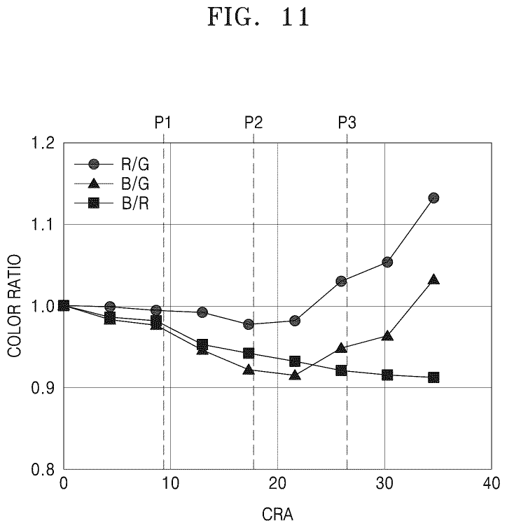

FIG. 10 is a graph illustrating the color ratio of an image derived when an anti-reflective coating according to an embodiment is not applied, and FIG. 11 is a graph illustrating the color ratio of an image derived when the anti-reflective coating according to an embodiment is applied.

In the graphs of FIGS. 10 and 11, the x-axis indicates an incident angle CRA of light incident to a color separation lens layer and the y-axis indicates a color ratio. According to an embodiment, the color ratio may be represented as the ratio values of red/green (R/G), blue/green (B/G), and blue/red (B/R).

Referring to FIG. 10, the image derived when an anti-reflective coating according to an embodiment is not applied may be an image with a waffle phenomenon. For example, the image derived when an anti-reflective coating according to an embodiment is not applied may have an interference pattern by losing the tendency of each color ratio in a first period (e.g., angle) CRF1, a second period (e.g., angle) CRF2, and a third period (e.g., angle) CRF3. That is, when an anti-reflective coating according to an embodiment is not applied, the ratio values of R/G, B/G, and B/R may deviate from a tendency in the first period CRF1, the second period CRF2, and the third period CRF3. For example, when the anti-reflective coating according to an embodiment is not applied, the ratio values R/G, B/G, and B/R may deviate from an intended curve at the specified angles CRF1, CRF2, and CRF3.

However, referring to FIG. 11, the image derived when an anti-reflective coating according to an embodiment is applied may not have an interference pattern in a first period (e.g., angle) P1, a second period (e.g., angle) P2, and a third period (e.g., angle) P3. For example, the image derived when an anti-reflective coating according to an embodiment is applied may not have an interference pattern by maintaining the tendency of each color ratio in the first period P1, the second period P2, and the third period P3. That is, when an anti-reflective coating according to an embodiment is applied, the ratio values of R/G, B/G, and B/R may maintain a tendency in the first period P1, the second period P2, and the third period P3.

While the inventive concept has been particularly shown and described with reference to embodiments thereof, it will be understood that various changes in form and details may be made therein without departing from the spirit and scope of the inventive concept.

What is claimed is:

1. An image sensor comprising a pixel array comprising a plurality of pixels, the plurality of pixels each comprising:
a sensor layer comprising a first light sensing cell and a second light sensing cell;
a color separation lens layer configured to receive first light having a first wavelength sensed by the first light sensing cell and second light having a second wavelength sensed by the second light sensing cell and change paths of each of the received first light and the received second light; and
an anti-reflective coating layer configured to reduce reflection of light received by the color separation lens layer,
wherein the anti-reflective coating layer has a grid pattern having the same shrink ratio as a grid pattern of the color separation lens layer.

2. The image sensor of claim 1, wherein the anti-reflective coating layer is further configured such that a phase of light incident to the color separation lens layer is the same as a phase of light incident to the anti-reflective coating layer.

3. The image sensor of claim 1, wherein a refractive index of the anti-reflective coating layer is lower than a refractive index of the color separation lens layer.

4. The image sensor of claim 1, wherein the anti-reflective coating layer comprises a plurality of anti-reflective coatings,
wherein the color separation lens layer comprises a plurality of color separation lenses, and
wherein the anti-reflective coating layer is further configured such that the grid pattern of the plurality of color separation lenses is aligned with the grid pattern of the plurality of anti-reflective coatings.

5. The image sensor of claim 4, wherein the anti-reflective coating layer is further configured such that a center of each of the plurality of anti-reflective coatings is aligned with a center of a respective color separation lens of the plurality of color separation lenses.

6. The image sensor of claim 4, wherein each of the plurality of color separation lenses has a cylindrical shape, and the plurality of anti-reflective coatings are on the plurality of color separation lenses, respectively.

7. The image sensor of claim 1, wherein the sensor layer comprises a plurality of light sensing cells having a red, green, and blue (RGB) pattern.

8. The image sensor of claim 1, wherein the color separation lens layer includes:
a plurality of tiers comprising a first tier including a plurality of first color separation lenses and a second tier disposed on top of the first tier and including a plurality of second color separation lenses corresponding one-to-one to the plurality of first color separation lenses;
wherein the anti-reflective coating layer includes:
a plurality of anti-reflective coatings, each of which is configured such that the center of each anti-reflective coating aligns with one of a plurality of average centers;
wherein the plurality of average centers are averages of the centers of the plurality of first color separation lenses and the centers of the plurality of second color separation lenses corresponding to each of the plurality of first color separation lenses.

9. A pixel array of an image sensor comprising a plurality of pixels, the pixel array comprising:
a sensor layer comprising a plurality of first light sensing cells and a plurality of second light sensing cells;
a color separation lens layer configured to receive first light having a first wavelength sensed by the plurality of first light sensing cells and second light having a second wavelength sensed by the plurality of second light sensing cells and change paths of each of the received first light and the received second light; and
an anti-reflective coating layer configured to reduce reflection of light received by the color separation lens layer,
wherein the anti-reflective coating layer has a grid pattern having the same shrink ratio as a grid pattern of the color separation lens layer.

10. The pixel array of claim 9, wherein the anti-reflective coating layer is further configured such that a phase of light incident to the color separation lens layer is the same as a phase of light incident to the anti-reflective coating layer.

11. The pixel array of claim 8, wherein a refractive index of the anti-reflective coating layer is lower than a refractive index of the color separation lens layer.

12. The pixel array of claim 9, wherein the anti-reflective coating layer comprises a plurality of anti-reflective coatings,
wherein the color separation lens layer comprises a plurality of color separation lenses, and
wherein the anti-reflective coating layer is further configured such that a grid pattern of the plurality of color separation lenses is aligned with the grid pattern of the plurality of anti-reflective coatings.

13. The pixel array of claim 12, wherein the anti-reflective coating layer is further configured such that a center of each of the plurality of anti-reflective coatings is aligned with a center of a respective color separation lens of the plurality of color separation lenses.

14. The pixel array of claim 12, wherein each of the plurality of color separation lenses has a cylindrical shape, and the plurality of anti-reflective coatings are on the plurality of color separation lenses, respectively.

15. The pixel array of claim 9, wherein the sensor layer comprises a plurality of light sensing cells having a red, green, and blue (RGB) pattern.

16. An electronic device comprising an image sensor comprising a pixel array comprising a plurality of pixels, the plurality of pixels each comprising:
a sensor layer comprising a first light sensing cell and a second light sensing cell;
a color separation lens layer configured to receive first light having a first wavelength sensed by the the first light sensing cell and second light having a second wavelength sensed by the the second light sensing cell and change paths of each of the received first light and the received second light; and
an anti-reflective coating layer configured to reduce reflection of light received by the color separation lens layer,
wherein the anti-reflective coating layer has a grid pattern having the same shrink ratio as a grid pattern of the color separation lens layer.

17. The electronic device of claim 16, wherein the anti-reflective coating layer is further configured such that a phase of light incident to the color separation lens layer is the same as a phase of light incident to the anti-reflective coating layer.

18. The electronic device of claim 16, wherein a refractive index of the anti-reflective coating layer is lower than a refractive index of the color separation lens layer.

19. The electronic device of claim 16, wherein the anti-reflective coating layer comprises a plurality of anti-reflective coatings,
wherein the color separation lens layer comprises a plurality of color separation lenses, and
wherein the anti-reflective coating layer is further configured such that a grid pattern of the plurality of color separation lenses is aligned with a grid pattern of the plurality of anti-reflective coatings.

20. The electronic device of claim 19, wherein the anti-reflective coating layer is further configured such that a center of each of the plurality of anti-reflective coatings is aligned with a center of a respective color separation lens of the plurality of color separation lenses.
